(19) United States
(12) Patent Application Publication
(10) Pub. No.: US 2013/0256915 A1
(43) Pub. Date: Oct. 3, 2013

(54) PACKAGING SUBSTRATE, SEMICONDUCTOR PACKAGE AND FABRICATION METHOD THEREOF

(71) Applicants: Huei-Nuan Huang, Taichung Hsien (TW); Chun-Tang Lin, Taichung Hsien (TW); Chien-Feng Chan, Taichung Hsien (TW); Chi-Hsin Chiu, Taichung Hsien (TW)

(72) Inventors: Huei-Nuan Huang, Taichung Hsien (TW); Chun-Tang Lin, Taichung Hsien (TW); Chien-Feng Chan, Taichung Hsien (TW); Chi-Hsin Chiu, Taichung Hsien (TW)

(73) Assignee: SILICONWARE PRECISION INDUSTRIES CO., LTD., Taichung (TW)

(21) Appl. No.: 13/614,590

(22) Filed: Sep. 13, 2012

(30) Foreign Application Priority Data
Apr. 2, 2012 (TW) 101111659

(51) Int. Cl. H01L 25/07; H01L 21/58; H01L 21/60; H01L 21/56

(52) U.S. Cl. 257/777; 438/108; 257/E25.018; 257/E21.503; 257/E21.505; 257/E21.511

(57) ABSTRACT

A semiconductor package includes a packaging substrate having a die attach area, a plurality of flow-guiding blocks disposed around an outer periphery of the die attach area, a first semiconductor element mounted on the die attach area, a second semiconductor element mounted on the first semiconductor element, and an underfill formed between the packaging substrate and the second semiconductor element. During filling of the underfill between the packaging substrate and the second semiconductor element, the flow-guiding blocks can guide a portion of the underfill to flow between the first semiconductor element and the second semiconductor element such that only one dispensing process is required for the underfill to completely encapsulate all conductive bumps used for flip-chip interconnection, thereby simplifying the fabrication process and improving the production efficiency.

### BACKGROUND OF THE INVENTION

1. Field of the Invention

The present invention relates to semiconductor packages and fabrication methods thereof, and, more particularly, to a packaging substrate, a semiconductor package and a fabrication method thereof for improving the product reliability.

2. Description of Related Art

Along with the rapid development of electronic industries, electronic products are developed to have a variety of functions and high performance. To meet the miniaturization requirement of semiconductor packages, wafer level packaging (WLP) technologies have been developed.

FIG. 1 is a schematic cross-sectional view of a conventional semiconductor package 1. The semiconductor package 1 comprises a packaging substrate 10 having opposite first and second surfaces 10a and 10b, a first semiconductor element 11 mounted on the first surface 10a, a second semiconductor element 12 mounted on the first semiconductor element 11, and underfills 16a and 16b.

The first surface 10a of the packaging substrate 10 has a plurality of conductive bumps 100 for electrically connecting the first semiconductor element 11. The second surface 10b of the packaging substrate 10 has a plurality of conductive pads 101 for solder balls 17 to be mounted on the conductive pads 101.

The first semiconductor element 11 has a plurality of through silicon vias (TSV) 111 therein.

The second semiconductor element 12 is mounted, in a flip-chip manner, on and electrically connected to the first semiconductor element 11 through a plurality of conductive bumps 120 so as to be further electrically connected to the packaging substrate 20 through the TSVs 211.

The underfill 16a is formed between the packaging substrate 10 and the first semiconductor element 11 for encapsulating the conductive bumps 100, and the underfill 16b is formed between the first semiconductor element 11 and the second semiconductor element 12 for encapsulating the conductive bumps 120. Since the gap x between the first and second semiconductor elements and the gap y between the first semiconductor element and the packaging substrate are not large, two dispensing processes need to be performed so as to dispense the underfills 16a and 16b in the gaps y and x, respectively.

However, compared with a single dispensing process, the two dispensing processes consume more time. In addition, after the dispensing processes, a baking process is required for curing the underfills. As such, the production efficiency is reduced.

Referring to FIG. 1′, if only one dispensing process is performed in order to improve the production efficiency, since the gap L between the second semiconductor element 12 and the packaging substrate 10 is large, the underfill 16 cannot flow upward into the gap x between the first and second semiconductor elements 11, 12 to encapsulate the conductive bumps 120, thus resulting in production failure. Therefore, only one dispensing process cannot realize an underfill process. Instead, two dispensing processes are required.

Further, when more semiconductor elements are stacked, the number of the dispensing processes also increases, thereby leading to lower production efficiency and adversely affecting the mass production.

Therefore, how to overcome the above-described drawbacks has become critical.

### SUMMARY OF THE INVENTION

In view of the above-described drawbacks, the present invention provides a semiconductor package, which comprises: a packaging substrate having a die attach area; a plurality of first flow-guiding blocks disposed around an outer periphery of the die attach area of the packaging substrate; a first semiconductor element mounted on the die attach area; a second semiconductor element mounted on the first semiconductor element; and an underfill formed between the packaging substrate and the second semiconductor element for encapsulating the first semiconductor element and the first flow-guiding blocks.

The present invention further provides a fabrication method of a semiconductor package, which comprises the steps of: providing a packaging substrate having a die attach area and a plurality of first flow-guiding blocks disposed around an outer periphery of the die attach area; mounting a first semiconductor element on the die attach area; mounting a second semiconductor element on the first semiconductor element; and forming an underfill between the packaging substrate and the second semiconductor element for encapsulating the first semiconductor element and the first flow-guiding blocks.

In the above-described semiconductor package and the fabrication method thereof, the first flow-guiding blocks can have a height greater than or equal to the height of the first semiconductor element.

In the above-described semiconductor package and the fabrication method thereof, the first semiconductor element can be mounted on the die attach area in a flip-chip manner.

In an embodiment, a gap is formed between a surface of the first semiconductor element and the top of each of the first flow-guiding blocks.

In the above-described semiconductor package and the fabrication method thereof, the area of second semiconductor element is greater than the area of the first semiconductor element.

In an embodiment, a gap is formed between a surface of the second semiconductor element and the top of each of the first flow-guiding blocks.

The above-described semiconductor package and the fabrication method thereof can further comprise a third semiconductor element and a fourth semiconductor element disposed between the first semiconductor element and the second semiconductor element. In an embodiment, the first semiconductor element has a bonding area and a plurality of second flow-guiding blocks disposed around an outer periphery of the bonding area, the third semiconductor element is bonded to the bonding area, and the fourth semiconductor element is interposed between the second semiconductor element and the third semiconductor element. The area of fourth semiconductor element is greater than the area of the third semiconductor element. Further, the underfill can encapsulate the second flow-guiding blocks, the third semiconductor element and the fourth semiconductor element.

The present invention further provides a packaging substrate, which comprises: a substrate body having a die attach area; and a plurality of first flow-guiding blocks disposed around an outer periphery of the die attach area.

According to the present invention, during filling of the underfill between the packaging substrate and the second semiconductor element, the first flow-guiding blocks (and the second flow-guiding blocks as well) serve as capillary structures to guide portions of the underfill to flow between the semiconductor elements such that only one dispensing process is required for the underfill to completely encapsulate all conductive bumps used for flip-chip interconnection, thereby simplifying the fabrication process and improving the production efficiency.

### BRIEF DESCRIPTION OF DRAWINGS

FIGS. 1 and 1′ are schematic cross-sectional views of a conventional semiconductor package;

FIGS. 2A to 2E are schematic cross-sectional views showing a fabrication method of a semiconductor package according to the present invention, wherein FIG. 2A′ shows another embodiment of FIG. 2A, and FIG. 2E′ shows another embodiment of FIG. 2E; and

FIGS. 3A to 3D are schematic upper views of a semiconductor package according to different embodiments of the present invention.

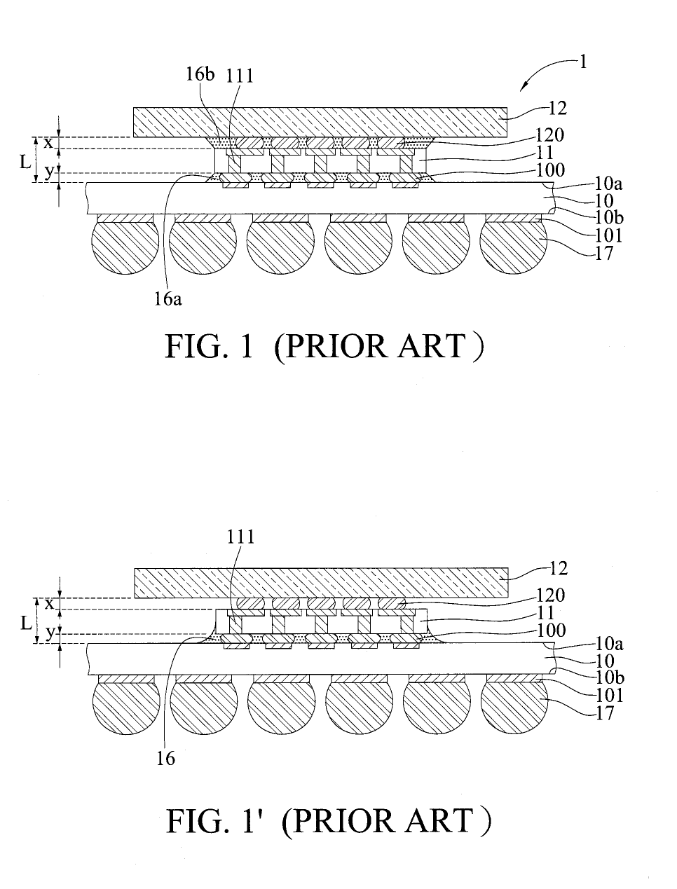

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that the drawings are only for illustrative purposes and not intended to limit the present invention. Meanwhile, terms such as ‘on’, ‘a’ etc. are only used as a matter of descriptive convenience and not intended to have any other significance or provide limitations for the present invention.

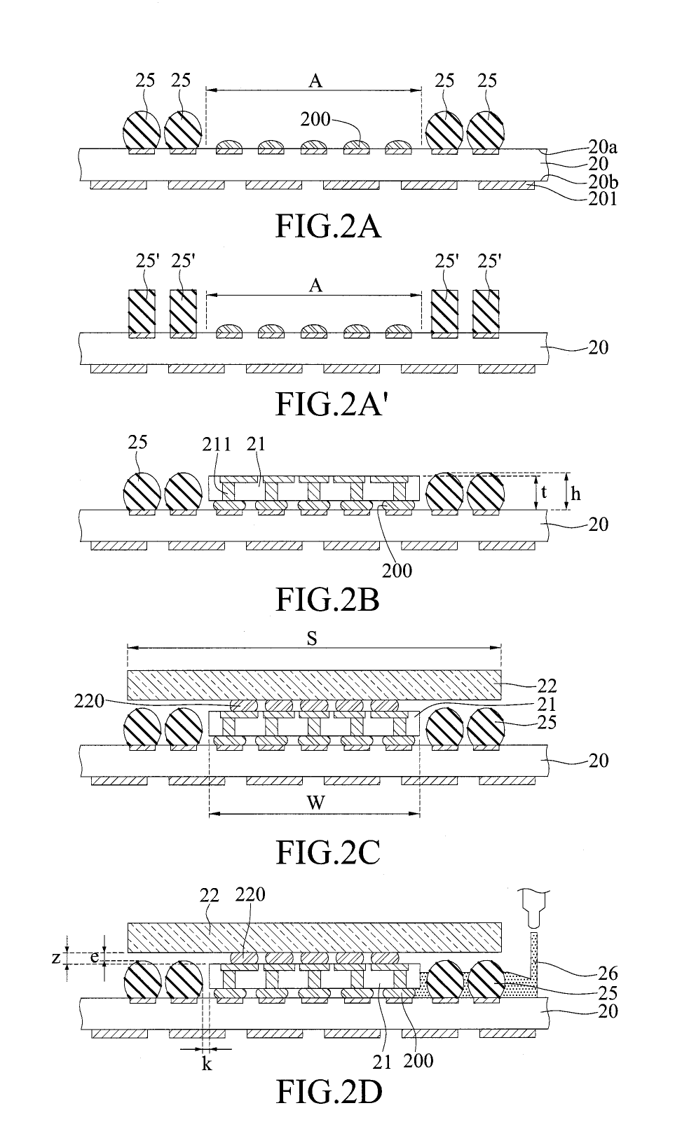

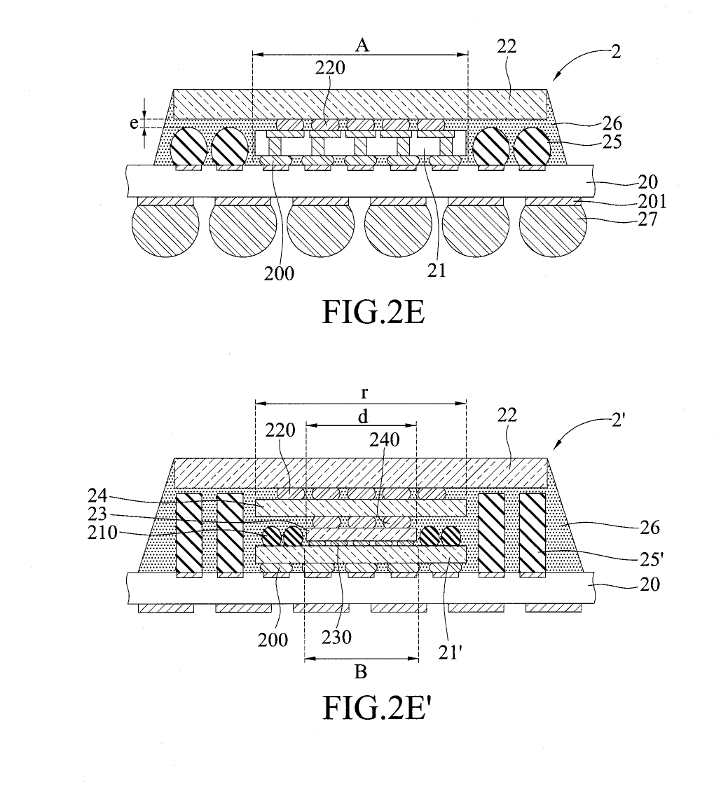

FIGS. 2A to 2E are schematic cross-sectional views showing a fabrication method of a semiconductor package 2 according to the present invention.

Referring to FIG. 2A, a packaging substrate 20 having a die attach area A is provided. The packaging substrate 20 can be a printed circuit board, a built-up substrate, a laminated board, a ceramic substrate, a silicon substrate or a glass substrate. A plurality of first flow-guiding blocks 25 are formed on the packaging substrate 20 around an outer periphery of the die attach area A, and a plurality of pre-solders 200 are formed on the packaging substrate 20 within the die attach area A.

In the present embodiment, the packaging substrate 20 has a first surface 20a and a second surface 20b opposite to the first surface 20a. The die attach area A is defined on the first surface 20a. The second surface 20b has a plurality of conductive pads 201 for electrical connection of an electronic device such as a circuit board (not shown).

The first flow-guiding blocks 25 can be made of, but not limited to, a metal material. Alternatively, the first flow-guiding blocks 25 can be made of a solder material, an electroplated metal block, an glue or the like. For example, a plurality of metal material can be formed through screen-printing, ball mounting or electroplating techniques so as to serve as the first flow-guiding blocks 25 and the pre-solders 200, respectively. It should be noted that the first flow-guiding blocks 25 do not serve as current conductive paths.

Each of the first flow-guiding blocks 25 can be in the shape of a ball. In another embodiment, referring to FIG. 2A′, each of the first flow-guiding blocks 25′ is in the shape of a column

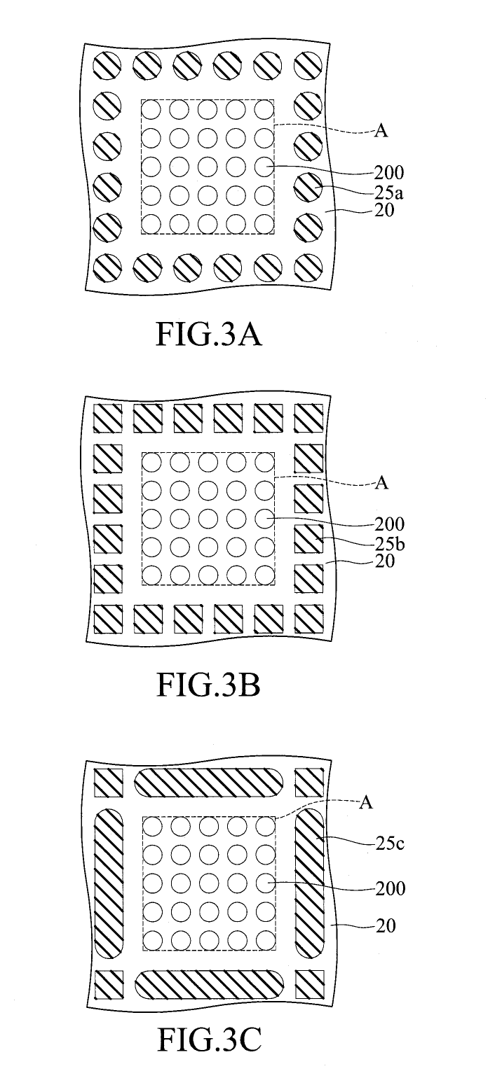

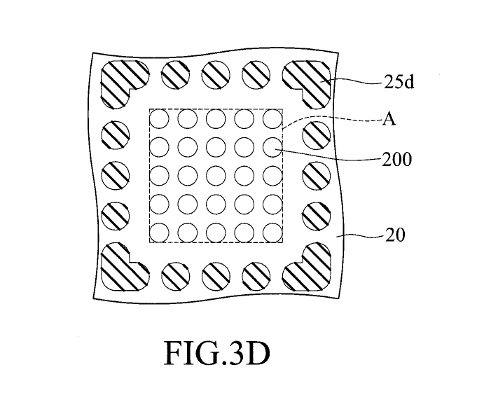

Further, referring to FIGS. 3A to 3D, the first flow-guiding blocks 25a, 25b, 25c and 25d can be disposed around the outer periphery of the die attach area A in different arrangements.

Referring to FIG. 2B, continued from FIG. 2A, a first semiconductor element 21 is mounted on and electrically connected to the pre-solders 200 in a flip-chip manner.

In the present embodiment, the first flow-guiding blocks 25 each have a height h greater than or equal to the height t of the first semiconductor element 21, and the first semiconductor element 21 is not in contact with the first flow-guiding blocks 25.

The first semiconductor element 21 is an interposer, which has a plurality of through silicon vias (TSV) 211 therein for electrically connecting the pre-solders 200, respectively.

Referring to FIG. 2C, a second semiconductor element 22 is mounted, in a flip-chip manner, on and electrically connected to the first semiconductor element 21 through a plurality of conductive bumps 220.

In the present embodiment, a gap is formed between the surface of the second semiconductor element 22 and the top of each of the first flow-guiding blocks 25, in other words, the second semiconductor element 22 is not in contact with the first flow-guiding blocks 25. The second semiconductor element 22 has an area S greater than the area W of the first semiconductor element 21 such that a portion of the second semiconductor element 22 is positioned over the first flow-guiding blocks 25.

The second semiconductor element 22 can be a semiconductor chip. Through electrical connection between the conductive bumps 220 and the TSVs 211, the second semiconductor element 22 is further electrically connected to the packaging substrate 20.

In other embodiments, the first semiconductor element 21 can be stacked on the second semiconductor element 22 first, and then the stacked structure is mounted on the packaging substrate 20.

Referring to FIGS. 2D and 2E, an underfill process is performed such that an underfill 26 is formed between the packaging substrate 20 and the second semiconductor element 22 for completely encapsulating the first semiconductor element 21, the pre-solders 200 and the first flow-guiding blocks 25. As such, a semiconductor package 2 is obtained.

The first flow-guiding blocks 25 are configured such that the gap e between the first flow-guiding blocks 25 and the second semiconductor element 22 is less than or equal to the gap z between the second semiconductor element 22 and the first semiconductor element 21. Therefore, a capillary phenomenon can occur during the underfill process. That is, the first flow-guiding blocks 25 guide a portion of the underfill 26 to flow upwards between the first semiconductor element 21 and the second semiconductor element 22. As such, both the conductive bumps 220 and the pre-solders 200 are encapsulated by the underfill 26. Therefore, only one dispensing process is required for the underfill to encapsulate the conductive bumps 220, the first semiconductor element 21 and the first flow-guiding blocks 25, thereby simplifying the fabrication process and improving the production efficiency.

Further, referring to FIG. 2D, the gap k between the first flow-guiding blocks 25 and the first semiconductor element 21 should not be too large. The gap k should be suitable so as for the capillary phenomenon to occur.

Furthermore, a plurality of solder balls 27 can be mounted on the conductive pads 201 of the second surface 20b of the packaging substrate 20 for electrical connection of a circuit board (not shown).

In another embodiment, referring to FIG. 2E′, the semiconductor package 2′ has more semiconductor elements. The first semiconductor element 21′ has a bonding area B and a plurality of second flow-guiding blocks 210 disposed around an outer periphery of the bonding area B. A third semiconductor element 23 is flip-chip mounted on and electrically connected to the bonding area B through a plurality of conductive bumps 230. A fourth semiconductor element 24 is mounted, in a flip-chip manner, on and electrically connected to the third semiconductor element 23 through a plurality of conductive bumps 240. The second semiconductor element 22 is mounted, in a flip-chip manner, on and electrically connected to the fourth semiconductor element 24. The first flow-guiding blocks 25′ are high above the fourth semiconductor element 24. The fourth semiconductor element 24 has a area r greater than the area d of the third semiconductor element 23. The underfill 26 encapsulates the second flow-guiding blocks 210, the conductive bumps 230 and 240, the third semiconductor element 23 and the fourth semiconductor element 24.

In the above-described semiconductor package, the first flow-guiding blocks 25′ and the second flow-guiding blocks 210 are used for guiding flow of the underfill. As such, only one dispensing process is required for the underfill to encapsulate all the conductive bumps 220, 230 and 240, thereby increasing the production efficiency.

The present invention further provides a semiconductor package 2, 2′, which has: a packaging substrate 20 having a die attach area A; a plurality of first flow-guiding blocks 25, 25′ disposed around an outer periphery of the die attach area A; a first semiconductor element 21 mounted on the die attach area A; a second semiconductor element 22 mounted on the first semiconductor element 21; and an underfill 26.

The packaging substrate 20 has a plurality of pre-solders 200 disposed within the die attach area A.

The first flow-guiding blocks 25 and 25′ have a height h greater than or equal to the height t of the first semiconductor element 21.

The first semiconductor element 21 is mounted on the die attach area A in a flip-chip manner and is not in contact with the first flow-guiding blocks 25 and 25′.

The second semiconductor element 22 is also not in contact with the first flow-guiding blocks 25 and 25′. The second semiconductor element 22 has a surface area S greater than the surface area W of the first semiconductor element 21.

The underfill 26 is disposed between the packaging substrate 20 and the second semiconductor element 22 for encapsulating the first semiconductor element 21 and the first flow-guiding blocks 25 and 25′.

In another embodiment, the semiconductor package 2′ further has a third semiconductor element 23 and a fourth semiconductor element 24 mounted between the first semiconductor element 21 and the second semiconductor element 22.

The first semiconductor element 21′ further has a bonding area B and a plurality of second flow-guiding blocks 210 disposed around an outer periphery of the bonding area B.

The third semiconductor element 23 is bonded to the bonding area B.

The fourth semiconductor element 24 is mounted between the second semiconductor element 22 and the third semiconductor element 23 and has a area r greater than the area d of the third semiconductor element 23. The first flow-guiding blocks 25′ have a height greater than or equal to the height of the fourth semiconductor element 24.

The underfill 26 encapsulates the second flow-guiding blocks 210, the third semiconductor element 23 and the fourth semiconductor element 24.

Therefore, the present invention uses a capillary structure, i.e., the first flow-guiding blocks 25 and 25′ and the second flow-guiding blocks 210, to guide flow of the underfill during an underfill dispensing process. As such, only one dispensing process is required for the underfill to encapsulate all the conductive bumps, thereby improving the production efficiency.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor package, comprising:
a packaging substrate having a die attach area;
a plurality of first flow-guiding blocks disposed around an outer periphery of the die attach area of the packaging substrate;
a first semiconductor element mounted on the die attach area;
a second semiconductor element mounted on the first semiconductor element; and
an underfill formed between the packaging substrate and the second semiconductor element for encapsulating the first semiconductor element and the first flow-guiding blocks.

2. The semiconductor package of claim 1, wherein a height of each of the first flow-guiding blocks is greater than or equal to that of the first semiconductor element.

3. The semiconductor package of claim 1, wherein the first semiconductor element is mounted on the die attach area in a flip-chip manner.

4. The semiconductor package of claim 1, wherein a gap is formed between a surface of the first semiconductor element and a top of each of the first flow-guiding blocks.

5. The semiconductor package of claim 1, wherein the second semiconductor element is of a surface area greater than that of the first semiconductor element

6. The semiconductor package of claim 1, wherein a gap is formed between a surface of the second semiconductor element and a top of each of the first flow-guiding blocks.

7. The semiconductor package of claim 1, further comprising a third semiconductor element and a fourth semiconductor element disposed between the first semiconductor element and the second semiconductor element.

8. The semiconductor package of claim 7, wherein the first semiconductor element has a bonding area and a plurality of second flow-guiding blocks disposed around an outer periphery of the bonding area, the third semiconductor element is bonded to the bonding area, and the fourth semiconductor element is interposed between the second semiconductor element and the third semiconductor element.

9. The semiconductor package of claim 7, wherein the area of fourth semiconductor element is greater in area than the third semiconductor element.

10. The semiconductor package of claim 7, wherein the underfill further encapsulates the second flow-guiding blocks, the third semiconductor element and the fourth semiconductor element.

11. A fabrication method of a semiconductor package, comprising the steps of:
providing a packaging substrate having a die attach area and a plurality of first flow-guiding blocks disposed around an outer periphery of the die attach area;
mounting a first semiconductor element on the die attach area;
mounting a second semiconductor element on the first semiconductor element; and
forming an underfill between the packaging substrate and the second semiconductor element for encapsulating the first semiconductor element and the first flow-guiding blocks.

12. The fabrication method of claim 11, wherein a height of each of the first flow-guiding blocks is greater than or equal to that of the first semiconductor element.

13. The fabrication method of claim 11, wherein the first semiconductor element is mounted on the die attach area in a flip-chip manner.

14. The fabrication method of claim 11, wherein a gap is formed between a surface of the first semiconductor element and a top of each of the first flow-guiding blocks.

15. The fabrication method of claim 11, wherein the second semiconductor element is greater in area than the first semiconductor element.

16. The fabrication method of claim 11, wherein a gap is formed between a surface of the second semiconductor element and a top of each of the first flow-guiding blocks.

17. The fabrication method of claim 11, further comprising disposing a third semiconductor element and a fourth semiconductor element between the first semiconductor element and the second semiconductor element.

18. The fabrication method of claim 17, wherein the first semiconductor element has a bonding area and a plurality of second flow-guiding blocks formed around an outer periphery of the bonding area, the third semiconductor element is bonded to the bonding area, and the fourth semiconductor element is interposed between the second semiconductor element and the third semiconductor element.

19. The fabrication method of claim 17, wherein the fourth semiconductor element is greater in area than the third semiconductor element

20. The fabrication method of claim 17, wherein the underfill encapsulates the second flow-guiding blocks, the third semiconductor element and the fourth semiconductor element.

21. A packaging substrate, comprising:
a substrate body having a die attach area; and
a plurality of first flow-guiding blocks disposed around an outer periphery of the die attach area.
